(19) United States
(12) Patent Application Publication
(10) Pub. No.: US 2018/0337020 A1
(43) Pub. Date: Nov. 22, 2018

(54) ION IMPLANT PLASMA FLOOD GUN PERFORMANCE BY USING TRACE IN SITU CLEANING GAS IN SPUTTERING GAS MIXTURE

(71) Applicant: ENTEGRIS, Inc., Billerica, MA (US)

(72) Inventor: Steven E. Bishop, Billerica, MA (US)

(21) Appl. No.: 15/778,002

(22) PCT Filed: Dec. 23, 2016
(86) PCT No.: PCT/US16/68529

§ 371 Date: May 22, 2018

Related U.S. Application Data
(60) Provisional application No. 62/271,278, filed on Dec. 27, 2015.

(51) Int. Cl. H01J 37/317

(52) U.S. Cl. CPC H01J 37/3171; H01J 2237/006; H01J 2237/3365; H01J 2237/0041; H01J 2237/022

(57) ABSTRACT

A gas supply assembly is described for delivery of gas to a plasma flood gun. The gas supply assembly includes: a fluid supply package configured to deliver inert gas to a plasma flood gun for generating inert gas plasma including electrons for modulating surface charge of a substrate in ion implantation operation; and cleaning gas in the inert gas fluid supply package in mixture with the inert gas, or in a separate cleaning gas supply package configured to deliver cleaning gas to the plasma flood gun concurrently or sequentially with respect to delivery of inert gas to the plasma flood gun. A method of operating a plasma flood gun is also described, in which cleaning gas is introduced to the plasma flood gun, intermittently, continuously, or sequentially in relation to flow of inert gas to the plasma flood gun. The cleaning gas is effective to generate volatile reaction product gases from material deposits in the plasma flood gun, and to effect re-metallization of a plasma generation filament in the plasma flood gun.

### FIELD OF THE INVENTION

The present disclosure generally relates to ion implantation equipment and processes, and more specifically relates to apparatus and methods for improving ion implant plasma flood gun performance.

### BACKGROUND

In the field of semiconductor manufacturing, ion implantation is a basic unit operation of semiconductor device fabrication. Ion implantation equipment may be of widely varying type, and may include beam ion implant systems, plasma immersion systems, and systems of other varied types.

In the use of beam ion implant systems, positively charged ions impinge on the wafer substrate being implanted, and this impingement may lead to build-up of positive charge on insulated regions of the wafer substrate, producing positive surface potentials. Wafer charging may also result from secondary emission of electrons from the wafer substrate. The wafer substrate surface charges may be sufficiently strong to adversely impact or even permanently damage integrated circuitry features of the wafer such as thin film transistor (TFT) circuits.

Plasma flood gun apparatus can be used to address such surface charge build-up, by generating plasma comprising low-energy electrons, so that the low-energy electrons can be dispersed into the ion beam and transported to the wafer surface to neutralize the charge build-up that would otherwise occur.

Plasma flood gun apparatus may be of varying types, but characteristically comprise an arc chamber arranged with an ionization filament element and coupled to a plasma tube circumscribed by solenoid coils, and communicating with an ion beam chamber. The ionization filament element in the arc chamber is formed of a refractory metal, often tungsten, and the gas used to form the low-energy electron plasma is characteristically an inert gas such as argon, krypton, or xenon, among other possibilities. A Faraday assembly may be included for confinement of the neutralizing electrons to the vicinity of the wafer, to thereby assist in mitigating wafer substrate charging, and typically include electron dose, uniformity, and charge measurement and monitoring components.

Thus, plasma flood gun apparatus address operational issues in beam ion implant systems, functioning to neutralize the beam plasma charge to control particle raisings, and reducing charge-up voltage on wafer substrates to prevent electrostatic destruction of thin film integrated circuitry elements.

### SUMMARY

In the operation of plasma flood gun systems to generate charge-neutralizing low-energy electrons, inert gas can incidentally sputter the plasma flood gun filament. The sputtered filament material becomes a gaseous material that can become deposited onto insulators and graphite components of the ion implant system as deposited contaminants. More generally, with extended operation, ion beam and condensable gas vapors deposit in, on, and around the plasma flood gun arc chamber, and its components. Such vapors also deposit on the Faraday (dose measurement) assembly to which the plasma flood gun is electrically coupled. Those deposits, regardless of their specific origin, are detrimental to the performance of the plasma flood gun system, and are detrimental to the operating lifetime of the system. In terms of performance, for example, these deposits are prone to result in electrical failure due to electrical shorting. Also relating to performance, sputtered filament material, e.g., tungsten, can make its way as into a wafer substrate being ion implanted, placing the sputtered filament material e.g., tungsten, as a contaminant in the substrate and reducing product yield of an ion implantation system and process.

These deposits can also decrease plasma flood gun emission currents, increase filament leakage currents, and, because the plasma flood gun is part of the dose measuring system, create Faraday leakage currents. All of these effects of deposited contaminants within an arc chamber of a flood gun can have a cumulative effect during operation, in a manner that can require regular maintenance, including cleaning of the deposited contaminants, and that can over time reduce the effective lifetime of a plasma flood gun. Researchers, therefore, continue to seek improvements in plasma flood gun technology to address and resolve the above-described operational issues. The present disclosure generally relates to ion implantation equipment and processes, and more specifically relates to apparatus and method for improving ion implant plasma flood gun performance.

The cleaning gas, when introduced into the arc chamber of the flood gun during operation, is effective to produce a desired cleaning effect within the flood gun arc chamber during operation. According to this description, a “cleaning effect” is an effect that the cleaning gas has within the arc chamber of a flood gun that is desired, beneficial, or advantageous, whereby the cleaning gas or a chemical component or derivative thereof interacts with a flood gun filament, or with residue deposited at the interior of the arc chamber, in a manner that improves one or more of a short-term performance characteristic, a longer term performance characteristic, or a lifespan of the plasma flow gun or an appurtenant ion implantation system.

One example of a type of cleaning effect is that the cleaning gas can be effective to generate volatile reaction product gases by interacting with material deposits that are present and accumulate at the interior of the plasma flood gun. By this effect, the material deposits can be volatilized by the cleaning gas and, thereby, removed from surfaces of the arc chamber. The deposits that are removed may be deposits that are present at a wall surface, and deposits present at an insulator. The result is that the amount of residues that build up on surfaces within the arc chamber during use are reduced relative the amount of residues that would be present on the surfaces in the absence of the cleaning gas.

This type of cleaning effect can advantageously result in reduced buildup of residues in the arc chamber. A direct result of this reduced buildup of residue can be improved performance of the plasma flood gun. Residue buildup in the chamber, e.g., at insulators, may cause electric failure due to shorting; a reduced level of residue will reduce or prevent the occurrence of electrical failure by shorting.

A different type of cleaning effect is that by volatizing the residues present at surfaces within the arc chamber, residues that originated from the filament of the plasma flood gun, that become volatized by use of the cleaning gas, may be re-deposited on the filament, effectively re-metallizing the filament in the plasma flood gun. A result can be extended filament life of the plasma flood gun filament relative to a lifetime of a filament that is used in the absence of the cleaning gas.

Alternately or additionally, a cleaning effect can be that the cleaning gas is effective to reduce sputtering of the filament. Sputtered filament material (e.g., tungsten) can become implanted as a contaminant in a substrate that is being ion implanted by a process that involves the plasma flood gun, causing a reduction in yield of the process. A reduction of sputtering of the filament will reduce the potential for substrate contamination by ion implantation of the filament material, thereby increasing yield of an ion implantation method that involves the plasma flood gun operated with cleaning gas as described.

In one aspect, the invention relates to a gas supply assembly for delivery of gas to a plasma flood gun. The gas supply assembly includes: a fluid supply package configured to deliver inert gas to a plasma flood gun for generating inert gas plasma including electrons for modulating surface charge of a substrate in ion implantation operation; and cleaning gas in the inert gas fluid supply package in mixture with the inert gas, or in a separate cleaning gas supply package configured to deliver cleaning gas to the plasma flood gun concurrently or sequentially with respect to delivery of inert gas to the plasma flood gun.

In another aspect, the invention relates to a method of operating a plasma flood gun configured to receive inert gas flowed to the plasma flood gun from an inert gas source, and to generate inert gas plasma therefrom including electrons energetically adapted to neutralize surface charge of a substrate being ion implanted. The method includes introducing to the plasma flood gun, intermittently, continuously, or sequentially in relation to flow of inert gas to the plasma flood gun, a cleaning gas that is effective to generate volatile reaction product gases from material deposits in the plasma flood gun, and to effect re-metallization of a plasma generation filament in the plasma flood gun.

Other aspects, features, and embodiments of the various novel and inventive subject matters of this disclosure will be more fully apparent from the ensuing description and appended claims.

### BRIEF DESCRIPTION OF THE DRAWINGS

FIG. 1 is a schematic representation of a plasma flood gun apparatus, showing the details of construction thereof.

FIG. 2 is a schematic representation of a beam ion implantation system utilizing a plasma flood gun apparatus in the beamline structure upstream of the wafer substrate being ion implanted.

FIG. 3 is a schematic representation of a gas supply assembly configured for delivery of gas to a plasma flood gun, in accordance with an illustrative embodiment of the present disclosure.

### DETAILED DESCRIPTION

The present disclosure relates generally to ion implantation equipment and processes, and more specifically to apparatus and methods for improving ion implant plasma flood gun performance.

The disclosure contemplates in one aspect a gas supply assembly for delivery of gas to a plasma flood gun, comprising: a fluid supply package configured to deliver inert gas to a plasma flood gun for generating inert gas plasma including electrons for modulating surface charge of a substrate in ion implantation operation; and cleaning gas in the inert gas fluid supply package in mixture with the inert gas, or in a separate cleaning gas supply package configured to deliver cleaning gas to the plasma flood gun concurrently or sequentially with respect to delivery of inert gas to the plasma flood gun.

In such gas supply assembly, the cleaning gas may be in the inert gas fluid supply package in mixture with the inert gas, in various embodiments.

In various embodiments, the cleaning gas may be in a separate cleaning gas supply package, and the assembly further comprises flow circuitry configured to receive cleaning gas from the cleaning gas supply package and inert gas from the inert gas fluid supply package, for mixing thereof to form a mixture of cleaning gas and inert gas for dispensing to the plasma flood gun.

In various embodiments, the flow circuitry may comprise a mixing chamber arranged to receive the cleaning gas and the inert gas from their respective fluid supply packages, for mixing thereof to form the mixture of cleaning gas and inert gas for dispensing to the plasma flood gun.

In various embodiments, the flow circuitry may comprise valving configured to selectively enable mixing of the cleaning gas and the inert gas in the mixing chamber, and alternatively to selectively enable the cleaning gas and the inert gas to be flowed separately to the plasma flood gun.

In various embodiments, the gas supply assembly may comprise a processor configured to control dispensing of cleaning gas from the cleaning gas supply package and separate dispensing of inert gas from the inert gas supply package. In such assembly, the processor may be configured to control dispensing of inert gas so that inert gas is dispensed continuously during ion implantation, and the processor is configured to control dispensing of cleaning gas so that cleaning gas is dispensed intermittently during a dispensing of inert gas, or so that cleaning gas is dispensed sequentially after dispensing of inert gas.

In the gas supply assembly variously described above, in various method embodiments, cleaning gas, when present in the plasma flood gun, is effective to generate volatile reaction product gases from material deposits in the plasma flood gun. The result can be a cleaning effect by which the material deposits can be volatilized and removed from surfaces of the arc chamber, and optionally also be carried out of (e.g., pumped out of) the arc chamber. The cleaning gas can be effective to remove deposits that are present at a wall surface of the arc chamber, at an insulator, or at other surfaces. By this cleaning effect, the amount of residues that are present and that build up on surfaces within the arc chamber during use are reduced when compared to amounts of the same residues that would be present on the surfaces, by operation of the plasma flood gun in an identical manner other than in the absence of the cleaning gas. A reduced presence of residue in the arc chamber can effect improved performance of the plasma flood gun. As one example, residue present at insulators can reduce or prevent the occurrence of electrical failure by shorting that may be directly caused by residue build on the insulators.

Additionally or in the alternate, removing deposits from surfaces of the arc chamber may also improve filament performance or filament lifetime. For example, volatizing residues present at surfaces within an arc chamber, if those residues originated from the filament of the plasma flood gun, may re-enter the arc chamber and become re-deposited on the filament, effectively re-metallizing the filament in the plasma flood gun. A result can be extended filament life of the plasma flood gun filament relative to a filament lifetime of an identical filament of an identical plasma flood gun operation in a manner that is identical except for not having the cleaning gas in the reaction chamber.

Alternately or additionally, a different potential cleaning effect can be that the cleaning gas is effective to reduce sputtering of the filament of the plasma flood gun during operation. Filament material (e.g., tungsten) that becomes sputtered and enters the arc chamber during use can make its way into an implantation beam operated in conjunction with the plasma flood gun. Once in the ion implantation beam, the filament material can become implanted as a contaminant in a substrate that is being ion implanted. The filament material, if present in the substrate, is a contaminant that reduces the yield of the ion implantation process. This cleaning effect of the present disclosure, i.e., reduction of sputtering of the filament material into the arc chamber, will reduce the potential for substrate contamination of an ion implant substrate by the filament material, thereby increasing yield of the ion implantation method that involves the plasma flood gun operated with cleaning gas as described, as compared to an identical method that does not use the cleaning gas in the plasma flood gun.

The cleaning gas in various embodiments of the gas supply assembly and methods of operating a flood gun assembly may include at least one gas selected from the group consisting of: F₂, O₂, H₂, HF, SiF₄, GeF₄, NF₃, N₂F₄, COF₂, C₂F₄H₂, and CₓO_{z}H_{y}F_{w}, wherein w, x, y, and z are each independently of zero or non-zero stoichiometrically appropriate value. For example, in the composition CₓO_{z}H_{y}F_{w}, w may in various embodiments be ≥1.

In example embodiments, a cleaning gas may comprise, consist of, or consist essentially of any one of these example gases alone or in a combination of two or more of these gases. A cleaning gas that consists essentially of a specific gas or combination of two or more of these gases is a cleaning gas that does not contain more than an insubstantial amount of other ingredient; this can mean, for example, that the cleaning gas contains not more than 5, 3, 2, 1, 0.5, or 0.1 percent by volume of another material that is not identified herein as a cleaning gas. (Generally, as used herein, any material or combination of materials, e.g., gases, that is said to “consist essentially of” one or more identified materials is one that contains the identified material or materials and not more than 5, 3, 2, 1, 0.5, or 0.1 percent by volume of any different material or materials; i.e., the combination includes at least 95, 97, 98, 99, 99.5, or 99.99 percent by volume of the listed materials.)

In embodiments wherein cleaning gas is supplied to a plasma flood gun as a mixture of cleaning gas and inert gas, the mixture may comprise, consist of, or consist essentially of an example cleaning gas as described (a single cleaning gas or a combination of two or more), and inert gas as described. A mixture (e.g., in a package, or otherwise used in a system or method as described) that consists essentially of cleaning gas and inert gas is a mixture that does not contain more than an insubstantial amount of any ingredient other than cleaning gas and inert gas as described; this can mean, for example, that the mixture contains cleaning gas, inert gas, and not more than 5, 3, 2, 1, 0.5, or 0.1 percent by volume of another material that is not identified herein as a cleaning gas or as an inert gas.

The inert gas in various embodiments may comprise at least one of argon, helium, nitrogen, xenon, and krypton.

A plasma flood gun apparatus may be variously constituted within the broad practice of the present disclosure as comprising a gas supply assembly as variously described herein. Similarly, the disclosure contemplates an ion implantation system comprising such plasma flood gun apparatus, as variously constituted.

The disclosure in a further aspect contemplates a method of operating a plasma flood gun configured to receive inert gas flowed to the plasma flood gun from an inert gas source, and to generate inert gas plasma therefrom including electrons energetically adapted to neutralize surface charge of a substrate being ion implanted, said method comprising introducing to the plasma flood gun, intermittently, continuously, or sequentially in relation to flow of inert gas to the plasma flood gun.

In the operation of plasma flood gun systems to generate charge-neutralizing low-energy electrons, inert gas sputters the plasma flood gun filament. The sputtered material becomes a gaseous filament material that can form deposits on insulators and graphite components of the ion implant system. With continued operation, ion beam and condensable gas vapors deposit in, on, and around the plasma flood gun arc chamber and its components. Such vapors also deposit on the Faraday (dose measurement) assembly to which the plasma flood gun is electrically coupled. The methods and cleaning gases described herein are effective to reduce, eliminate, or ameliorate these effects by producing a cleaning effect as described herein. One type of cleaning effect is that when used in a method as described, a cleaning gas can be effective to generate volatile reaction product gases from material deposits in the plasma flood gun. This can result in a reduced presence of such material deposits in the arc chamber, i.e., an arc chamber that is cleaner relative to an identical arc chamber operated identically except without the use of the cleaning gas. The reduction in material deposits can in turn improve short term performance of the plasma flood gun and can extend the product life of the plasma flood gun. Additionally or alternately, a cleaning effect of the cleaning gas can be to effect re-metallization of a plasma generation filament in the plasma flood gun.

In various embodiments of such methodology, the cleaning gas may be introduced to the plasma flood gun intermittently in relation to flow of inert gas to the plasma flood gun.

In various embodiments of the methodology, the cleaning gas may be introduced to the plasma flood gun continuously in relation to flow of inert gas to the plasma flood gun.

In various embodiments of the methodology, the cleaning gas may be introduced to the plasma flood gun sequentially in relation to flow of inert gas to the plasma flood gun.

In various embodiments of the methodology, the cleaning gas maybe flowed to the plasma flood gun in mixture with the inert gas.

The above-discussed method may be carried out, with the cleaning gas and the inert gas provided to the plasma flood gun from separate gas supply packages. For example, the cleaning gas and inert gas may be mixed with one another exteriorly of the plasma flood gun. By example methods, the admixture does not contain any gas other than cleaning gas and inert gas, and no other gas is supplied to the plasma flood gun other than the cleaning gas and the inert gas, i.e., the gases supplied to the plasma flood gun, e.g., separately or in admixture, consist of or consist essentially of the cleaning gas and the inert gas.

The method may be carried out, wherein the cleaning gas comprises, consists of, or consists essentially of fluorine, oxygen, hydrogen, hydrogen fluoride, cobalt difluoride or a combination thereof.

The method may be carried out, wherein the inert gas comprises, consists of, or consists essentially of argon, helium, nitrogen, xenon, krypton or a combination thereof.

The disclosure contemplates a method of operating an ion implantation system to increase operating life between maintenance events, wherein the ion implantation system comprises a plasma flood gun, and the method includes operating the plasma flood gun according to any mode variously described herein, including the use of a cleaning gas.

As discussed in the Background section hereof, operational issues have characterized the use of plasma flood gun apparatus in beam ion implant systems, including filament-derived tungsten or other refractory metal deposition on insulators and graphite components of the ion implant system, and deposition of other unwanted materials at the arc chamber and Faraday assembly regions of the plasma flood gun in such ion implant system.

As a general operational protocol, plasma flood guns are designed to be periodically maintained, e.g., on a quarterly calendar year basis, but very frequently they require early replacement after only a short period of operation, which may be on the order of only a few weeks. This is disadvantageous, because the plasma flood gun is part of the Faraday, dose, uniformity and charge monitor components of the ion implant system, and wafer requalification is required with each plasma flood gun vacuum break.

The present disclosure provides various solutions to such operational issues. In various embodiments, an in situ cleaning gas is admixed with inert gas that is flowed to the arc chamber of the plasma flood gun. Such admixture may involve provision of a corresponding mixture in a single gas supply vessel used to provide inert source gas (inert gas) to the plasma flood gun arc chamber, so that the mixture is dispensed from such single gas supply vessel to the plasma flood gun. In other embodiments, separate gas supply vessels of inert source gas and in situ cleaning gas may be used, in which the cleaning gas and inert source gas are co-flowed in separate lines to the arc chamber for mixing therein to form the admixed gas, or in which the respective cleaning gas and inert source gas are flowed to a mixing chamber to form the admixed gas that then is flowed in a feed line to the arc chamber of the plasma flood gun, or in which cleaning gas is flowed from a separate gas supply vessel to a gas feed line transporting the inert gas from a separate gas supply vessel to the arc chamber of the plasma flood gun, so that the cleaning gas mixes with the inert source gas in the feed line and is delivered in the admixed gas to the arc chamber of the plasma flood gun. As a further variation, the cleaning gas may be periodically injected into the plasma flood gun arc chamber or an inert gas feed line to the arc chamber. Results, i.e., cleaning effects, of the methods can be to reduce the continued or ongoing buildup of deposited residues at surfaces or components of the plasma flood gun during operation; to effect (e.g., periodic) re-metallization (e.g., re-tungstenization) of the plasma flood gun arc chamber filament; or to effect periodic removal of unwanted deposits from the plasma flood gun and associated ion implant system structure.

Thus, the disclosure contemplates method embodiments that involve providing continuous flow of cleaning gas to the plasma flood gun arc chamber during concurrent continuous flow of inert source gas to such arc chamber, e.g., as a premixed gas mixture from a source vessel containing same, or in various co-flow arrangements in which separate gas supply vessels of inert gas and cleaning gas supply their respective gases directly to the arc chamber, or to a mixing structure (dedicated mixing chamber or injection of the cleaning gas to the feed line for the inert gas being flowed to the arc chamber of the plasma flood gun) upstream of the arc chamber. The disclosure also contemplates periodic (e.g., cyclic or acyclic) delivery of cleaning gas to the plasma flood gun arc chamber during continuous or intermittent flow of inert source gas to such arc chamber.

In instances in which the inert gas and cleaning gas are premixed in a unitary gas mixture that is packaged in a single gas supply vessel, the relative proportions of the inert gas and cleaning gas are desirably such as to produce a desired cleaning effect, for example to result in continuous or intermittent removal of deposits in the plasma flood gun assembly and associated beamline regions of the ion implant system, optimal suppression of remediation of a loss of filament material (e.g., tungsten) from the filament by re-metallizing the filament and optionally to establish an equilibrium in which loss of filament material by sputtering is minimized or even eliminated during the operation of the plasma flood gun.

Likewise, in other modes of separate delivery of inert gas and cleaning gas, the relative proportions of the cleaning gas to the inert gas will be selected correspondingly, to achieve such continuous or intermittent removal of deposits and suppression or remediation of loss from the filament in the arc chamber of the plasma flood gun.

It will therefore be appreciated that the concentrations of the cleaning gas as compared to the inert gas can be relatively smaller when the cleaning gas is being concurrently and continuously flowed to the plasma flood gun arc chamber, and that periodic injection of cleaning gas into the inert gas may entail relatively larger concentrations of cleaning gas being employed, to achieve a desired cleaning effect or re-metallization (e.g., re-tungstenization) of the filament in the arc chamber of the plasma flood gun.

Thus, the disclosure contemplates various techniques for admixing of in situ cleaning gas with inert gas to produce a desired cleaning effect, e.g., to transport filament material such as tungsten to the plasma flood gun filament, or to more generally form volatile reaction product gases, e.g., volatile fluorides in the case of fluorocompound cleaning gases, from reaction with deposits, so that the resulting reaction product gases can be readily removed from the ion implant system. By certain embodiments, removal of the volatile reaction product gases from the plasma flood gun arc chamber can be effected in the normal discharge of effluent gases from the ion implant system, with the volatile reaction product gases being entrained in and discharged with other effluent gases from the system. Additionally, or alternatively, pumping operations may be conducted to remove such volatile reaction product gases, such as by pumping gas out of the arc chamber during a step of periodically injecting cleaning gas into the inert gas being flowed to the plasma flood gun arc chamber.

The cleaning gas and inert gas as mentioned may be admixed in a unitary gas supply vessel, or separate vessels for each of the cleaning gas and inert gas may be employed. The gas supply vessels in either case can be of any suitable type, and may for example comprise high-pressure gas cylinders, or internally pressure-regulated gas supply vessels, such as those commercially available from Entegris, Inc. (Billerica, Mass., USA) under the trademark VAC®, or adsorbent-based gas supply vessels, such as those commercially available from Entegris, Inc. (Billerica, Mass., USA) under the trademark SDS®.

The in situ cleaning gas may be of any suitable type that is effective to produce a cleaning effect as described herein, such as to remove or prevent the accumulation of deposits at surfaces of the plasma flood gun assembly; for suppressing or remediating demetallization by sputtering of the tungsten filament of the plasma flood gun assembly; or for a combination of these. In specific embodiments, the in situ cleaning gas may for example comprise, consist of, or consist essentially of at one or more gases selected from the group consisting of F₂, O₂, H₂, HF, SiF₄, GeF₄, NF₃, N₂F₄, COF₂, C₂F₄H₂, and CₓO_{z}H_{y}F_{w}, wherein w, x, y, and z are each independently of zero or non-zero stoichiometrically appropriate value. In applications in which the cleaning gas includes gas of the composition CₓO_{z}H_{y}F_{w}, w may in various embodiments be ≥1. In other embodiments, the cleaning gas may comprise, consist of, or consist essentially of any mixture of two or more of the foregoing gas species.

The inert gas likewise may be of any suitable type that is usefully employed in the plasma flood gun assembly to generate low-energy electrons for charge neutralization at the wafer surface in the ion implantation system. In specific embodiments, the inert gas may for example comprise, consist of, or consist essentially of argon, helium, nitrogen, xenon, krypton, or the like, as well as mixtures of two or more of such gas species.

The in situ cleaning gas/inert gas mixtures may comprise, consist of, or consist essentially of these gases in any suitable concentrations and relative proportions. In various embodiments, it may be advantageous to use the in situ cleaning gas (which may be of single component as well as multicomponent composition) at concentrations of from 0.01% to 60% by volume, based on total volume of the overall gas mixture (of in situ cleaning gas and inert gas). In other embodiments, the concentration of the in situ cleaning gas may be in a range the lower limit of which is 0.1, 0.5%, 1%, 2%, 5%, 10%, 12%, 15%, 18%, 20%, 25%, 30%, 35%, 40%, 45%, or 50%, by volume, and the upper limit of which is above the lower limit and which may in various compositions be 1%, 2%, 5%, 10%, 12%, 15%, 18%, 20%, 25%, 30%, 35%, 40%, 45%, 50%, 55%, or 60%, by volume, wherein the percentages are based on the total volume of the overall gas mixture. In particular applications, the concentration of the in situ cleaning gas may be in a range of from 0.05% to 20%, or a range of from 0.5% to 12%, or a range of from 1% to 5%, or any other suitable range including one of the above-identified lower limit and one of the above-identified upper limit values, based on total volume of the overall gas mixture (of in situ cleaning gas and inert gas).

It will therefore be understood that the specific gas composition used in a given application of the present disclosure may be varied substantially depending on the particular plasma flood gun ion implant apparatus, the plasma flood gun operating lifetime, the emission currents, filament leakage currents, Faraday leakage currents and other operational characteristics of the apparatus, as well as the specific ion beam species being implanted in the substrate wafers in the operation of the apparatus.

When the in situ cleaning gas is supplied in mixture with the inert gas in the first instance, for dispensing in such admixed form from a unitary fluid supply vessel, the flow rate of the in situ cleaning gas/inert gas mixture that is flowed to the arc chamber of the plasma flood gun may be widely varied in the broad practice of the present disclosure. In various plasma flood gun ion implant operations for manufacture of semiconductor products, flow rates of the mixture may for example be in a range of from 0.5 to 1 standard cubic centimeter per minute (sccm). In flat-panel display (FPD) implant operations, the flow rate of the in situ cleaning gas/inert gas mixture may in specific embodiments be in a range of from 3 to 5 sccm.

When the in situ cleaning gas and the inert gas are supplied in (at least initially) separate streams, the flow rates of the respective separate streams may be correspondingly varied and determined to achieve relative concentrations of gases deriving from such streams that are sufficient to produce a cleaning effect as described herein, such as to effect removal of deposits in the plasma flood gun assembly, to re-metallize (e.g., re-tungstenize) a filament therein, while also effecting charge neutralization generation of low-energy electrons from the inert gas.

Thus, as discussed above, in various embodiments, the inert gas and the in situ cleaning gas may be supplied in the first instance as a gas mixture from a unitary gas supply vessel. In other embodiments, the inert gas and in situ cleaning gas may be provided in separate vessels at the site of the plasma flood gun and ion implant apparatus, with the separate vessels dispensing their respective gases to separate flow lines to the plasma flood gun and ion implanter apparatus, for mixing in the apparatus. Alternatively, the separate dispensing lines may dispense gas to a common feed line upstream of the plasma flood gun and ion implanter apparatus, so that the respective gases are intermixed in their flow through the common feed line. As a still further alternative, the separate vessels may dispense respective gases to a mixing chamber, from which the mixed gas flows through a single feed line to the plasma flood gun and ion implanter apparatus. Accordingly, unitary gas mixture fluid supply is contemplated, as well as co-flow arrangements, it being necessary only that the respective gases are combined at or upstream of the plasma flood gun and ion implanter apparatus to provide an admixed gas for generation of low-energy electrons from the inert gas as well as cleaning of the plasma flood gun, re-metallization of the plasma flood gun filament, or both.

In other instances in which the in situ cleaning gas and the inert gas are supplied from separate sources and mixed at the point of use of the plasma flood gun apparatus, it may be advantageous to provide capability in the gas supply circuitry for flow only of the in situ cleaning gas into the ion implant apparatus, while the inert gas is not flowing, in order to provide a high intensity clean of the plasma flood gun. This could be accommodated by a supply vessel and manifold arrangement configured to enable a purge flow of the in situ cleaning gas into the plasma flood gun apparatus, to sweep other gases from the apparatus and enable the cleaning operation of the plasma flood gun to take place, as an intermittent cleaning operation.

Such intermittent high intensity cleaning may be preferred in various embodiments to increase the operating life of the apparatus, and may be integrated as part of the preventive maintenance for the plasma flood gun ion implant apparatus.

In other modes of operation, instead of conducting a dedicated clean operation with concurrent feeding of the admixed in situ cleaning gas and inert gas, it may be desirable to periodically cycle purge an amount of the in situ cleaning gas into the inert gas being flowed into the plasma flood gun ion implant apparatus for normal plasma generation operation, or to periodically cycle purge an amount of the in situ cleaning gas directly into the arc chamber of the plasma flood gun, so that the in situ cleaning by the in situ cleaning gas is carried out automatically and on a periodic basis. This can be accommodated, for example, by utilizing a cycle timer program and a gas cabinet or valve manifold box (VMB) that is configured to mix the in situ cleaning gas into the inert gas to achieve a predetermined concentration of the cleaning gas in the cleaning gas/inert gas mixture.

The approach of the present disclosure, of using an in situ cleaning gas concurrently, intermittently, or sequentially (altematingly) with an inert process gas to reactively remove deposited build-up of sputtered filament material such as tungsten, and other deposited residues, to improve plasma flood gun and implanter performance, to remetallize the filament in the plasma flood gun, or both, achieves a substantial advance in the art. Relative to identical operation of an identical plasma flood gun operated without the use of cleaning gas as described herein, advantages of the use of a cleaning gas include improving the operational service life of a plasma flood gun in an ion implanter, reducing maintenance events for such equipment, and reducing the occurrence of deleterious operation of the plasma flood gun that can significantly degrade implanter performance.

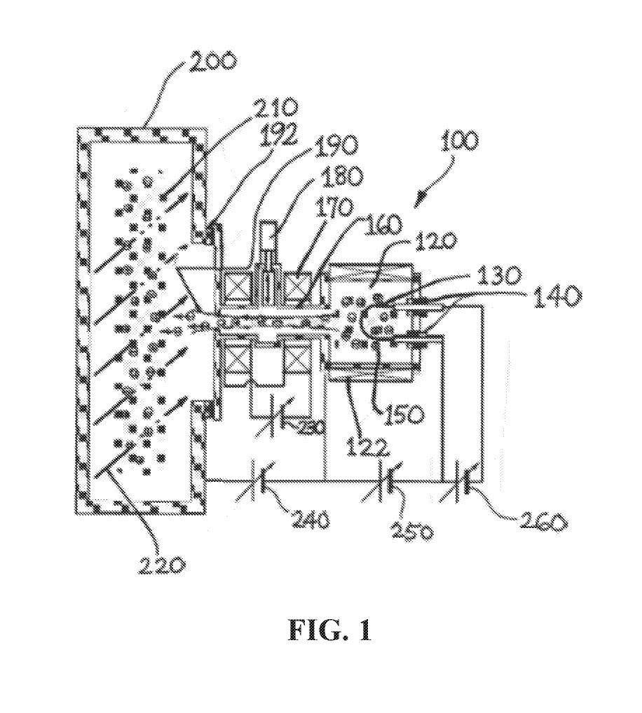

Referring now to the drawings, FIG. 1 is a schematic representation of a plasma flood gun apparatus 100, showing the details of construction thereof.

The plasma flood gun apparatus includes an arc chamber 120 in which is disposed a filament 130 supported by insulators 140 at the wall of the arc chamber, and joined by electrical circuitry to the filament power supply 260. When energized, the filament 130 generates a plasma 150 in the arc chamber 120. The arc chamber is provided with magnets 122 at an exterior surface thereof. The arc chamber is electrically coupled with the arc power supply 250, as shown. The arc chamber is coupled with a plasma tube 160 that is circumscribed by solenoid coils 170 that are energized by a solenoid coil power supply 230. The plasma tube 160 is equipped with a maintenance valve 180 for the plasma tube. The plasma tube in turn communicates with the ion beam chamber 200 containing beam plasma 210. The magnetic field 190 emitting from the plasma tube 160 is angularly directed to the direction of the ion beam 220 in the ion beam chamber. The ion beam chamber 200 is coupled with an external power supply 240 as part of the power supply circuitry of the plasma flood gun apparatus. The plasma tube 160 is electrically isolated from the ion beam chamber 200 by the isolator.

In operation, the plasma flood gun apparatus of FIG. 1 operates with the filament energized to form a plasma containing low-energy electrons from inert gas introduced to the arc chamber, with the low-energy electrons being dispersed into the ion beam in the ion beam chamber 200, for charge neutralization at the surface of the wafer substrate (not shown in FIG. 1).

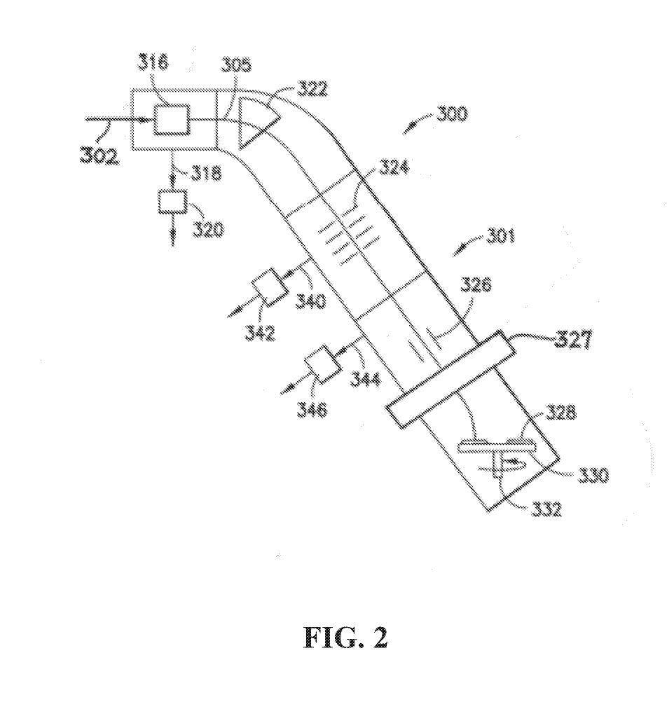

FIG. 2 is a schematic representation of a beam ion implantation system 300 utilizing a plasma flood gun apparatus in the beamline structure upstream of the wafer substrate being ion implanted.

In the illustrated system 300, the ion implant chamber 301 contains an ion source 316 receiving dopant source gas from line 302 and generates an ion beam 305. The ion beam 305 passes through the mass analyzer unit 322 which selects the ions needed and rejects the non-selected ions.

The selected ions pass through the acceleration electrode array 324 and then the deflection electrodes 326. The resulting focused ion beam then passes through the plasma flood gun 327 which operates to disperse low-energy electrons into the ion beam, and the ion beam augmented with such low-energy electrons then is impinged on the substrate element 328 disposed on the rotatable holder 330 mounted on spindle 332. The ion beam of dopant ions thereby dopes the substrate as desired to form a doped structure, and the low-energy electrons serve to neutralize charge buildup on the surface of the substrate element 328.

The respective sections of the ion implant chamber 301 are exhausted through lines 318, 340 and 344 by means of pumps 320, 342 and 346, respectively.

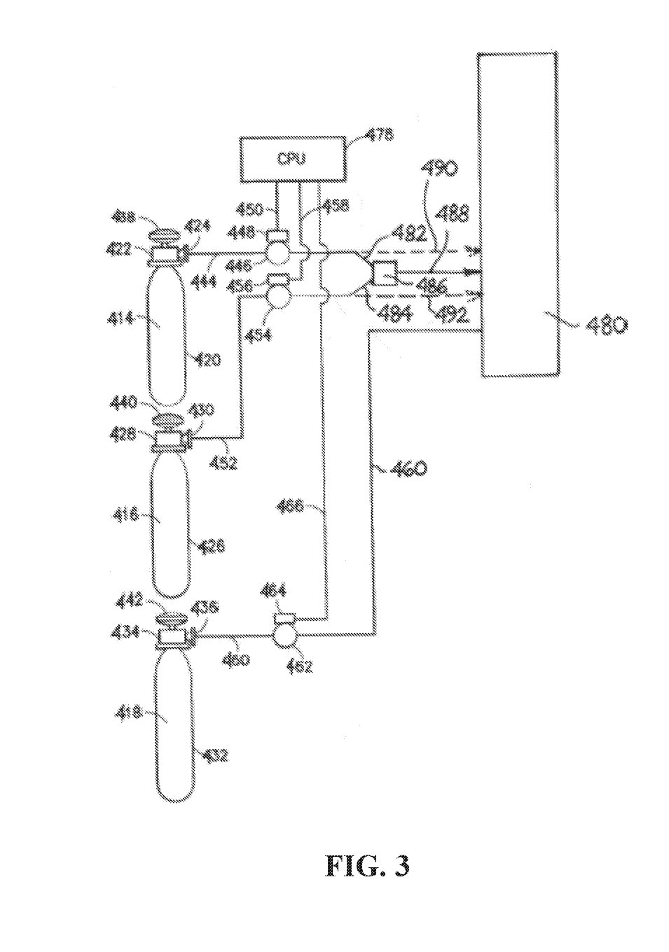

FIG. 3 is a schematic representation of a gas supply assembly configured for delivery of gas to a plasma flood gun, in accordance with an illustrative embodiment of the present disclosure.

The plasma flood gun 480 is shown in FIG. 3 as being arranged in fluid receiving relationship to three gas supply packages 414, 416, and 418, for demonstration of various operational modalities of the gas supply assembly. The gas supply package 418 includes a vessel 432 with a valve head assembly 434 with a discharge port 436 joined to gas feed line 460. The valve head assembly 434 is equipped with a hand wheel 442, for manual adjustment of the valve in the valve head assembly, to translate same between fully open and fully closed positions, as desired, to effect dispensing operation, or alternatively, closed storage of the gas mixture in vessel 432. The hand wheel 442 may be substituted by a valve actuator that is automatically controlled to modulate the setting of the valve in the valve head assembly, e.g., a pneumatic valve actuator operably linked to CPU 478.

The vessel 432 contains an in situ cleaning gas/inert gas mixture, which may for example comprise 5% by volume of fluorine gas as the in situ cleaning gas, and 95% by volume of xenon as the inert gas. The gas feed line 460 as shown contains a flow control valve 462 therein. The flow control valve 462 is equipped with an automatic valve actuator 464, having signal transmission line 466 connecting the actuator to CPU 478, whereby CPU 478 can transmit control signals in signal transmission line 466 to the valve actuator to modulate the position of the valve 462, to correspondingly control the flow of the cleaning gas/inert gas mixture from the vessel 432 to the plasma flood gun assembly 480.

As an alternative to the supply of an in situ cleaning gas/inert gas mixture to the plasma flood gun, as existing in premixed form in vessel 432, the gas supply assembly of FIG. 3 includes an alternative arrangement, in which the fluid supply package 414 includes an inert gas in the vessel 420, and in which the fluid supply package 416 includes cleaning gas in vessel 426.

The fluid supply package 414 includes the vessel 420 with a valve head assembly 422 with a discharge port 424 joined to gas feed line 444, for dispensing inert gas from the vessel 420, as previously described. The valve head assembly is equipped with hand wheel 438, which as in the case of fluid supply package 418, may be substituted with an automatic valve actuator operably linked to CPU 478.

In like manner, the fluid supply package 416 includes the vessel 426 with a valve head assembly 428 with a discharge port 430 joined to gas feed line 452, for dispensing cleaning gas from the vessel 426, as previously described. The valve head assembly is equipped with hand wheel 440, which may be substituted with an automatic valve actuator operably linked to CPU 478.

In the FIG. 3 system, the inert gas feed line 444 contains flow control valve 446 equipped with actuator 448 operably linked by signal transmission line 450 to CPU 478. Correspondingly, the cleaning gas feed line 452 contains flow control valve 454 equipped with valve actuator 456 operably linked by signal transmission line 458 to CPU 478. By such arrangement, the CPU 478 may be programmably configured to carry out the dispensing operation of the inert gas from inert gas supply vessel 420 and the dispensing operation of the cleaning gas from cleaning gas supply vessel 426, as desired.

As illustrated in FIG. 3, the inert gas feed line 444 downstream of the flow control valve 446 includes a terminal feed line section 482 joined to the mixing chamber 486. Likewise, the cleaning gas feed line 452 downstream of the flow control valve 454 includes a terminal feed line section 484 joined to the mixing chamber 486. By this arrangement, inert feed gas and cleaning gas can be introduced in the respective terminal feed line sections to the mixing chamber, for mixing thereof and subsequent flow from the mixing chamber 486 in the gas feed line 488 to the plasma flood gun 480. The relative proportions of the respective inert gas and cleaning gas components of the mixture discharged from mixing chamber 486 may be controllably set by appropriate modulation of the flow control valves 446 and 454 in the respective gas feed lines 444 and 452.

As a further alternative in the FIG. 3 system, the inert gas feed line 444 may be connected to the inert gas feed line 490 shown in dashed line representation, for direct introduction of the inert gas to the plasma flood gun apparatus, e.g., directly to the arc chamber of such apparatus. Correspondingly, the cleaning gas feed line 452 may be connected to the cleaning gas feed line 492 shown in dashed line representation, for direct introduction of the cleaning gas to the plasma flood gun apparatus, e.g., directly to the arc chamber of such apparatus. In this manner, the co-flowed inert gas and cleaning gas streams are directly introduced to the plasma flood gun and are admixed with one another in the arc chamber of the apparatus.

The FIG. 3 system can also be operated so that inert gas from vessel 420 is continuously flowed to the plasma flood gun 480 during ion implantation operation of the implanter apparatus in which the plasma flood gun 480 is disposed, while at the same time, the cleaning gas from vessel 426 is introduced to the plasma flood gun only intermittently, e.g., at predetermined cyclic intervals, so that cleaning action and re-metallizing of the filament is effected at such predetermined cyclic intervals, or otherwise in a periodic manner.

As a still further modification of operation in the FIG. 3 system, the cleaning gas, by appropriate valving in the cleaning gas feed lines 452, 492, and/or terminal feed line section 484, may be flowed separately to the plasma flood gun at periodic intervals or otherwise as necessary, during concurrent flow of inert gas to the plasma fusion gun, or alternatively after flow of inert gas to the plasma fusion gun has been terminated, so that only cleaning gas is flowed to the plasma fusion gun apparatus. The valving may accommodate such separate independent operation of cleaning gas flow, without concurrent inert gas flow to the plasma flood gun, and the valving may be modulated, e.g., by appropriate link to the CPU 478, to switch the cleaning gas to the mixing chamber 486 for mixing with inert gas flowed to the mixing chamber, as another mode of operation.

It will therefore be appreciated that the FIG. 3 system may be variously configured to accommodate multiple modes of operation, including flow of premixed inert gas/cleaning gas from a unitary gas supply vessel, co-flow of inert gas and cleaning gas to the plasma flood gun, co-flow of inert gas and cleaning gas to a mixing chamber upstream of the plasma flood gun, periodic introduction of cleaning gas to the plasma flood gun, with or without concurrent inert gas flow to the plasma flood gun (periodic or intervallic cleaning mode), or periodic introduction of cleaning gas to the inert gas stream via the mixing chamber. It will correspondingly be appreciated that the CPU 478 illustratively shown in such system may comprise a processor of any suitable type or types, including a special purpose programmed computer, a programmable logic controller, microprocessor, etc., and that the CPU may be programmable configured to carry out any of the aforementioned modes of operation involving the cleaning gas.

Finally, it will be appreciated that the utilization of cleaning gas in the plasma flood gun operation as herein variously disclosed, achieves a substantial advance in the art, in enabling the operating life of the plasma flood gun to be substantially increased, and the overall efficiency of the ion implantation system to be enhanced.

While the disclosure has been set forth herein in reference to specific aspects, features and illustrative embodiments, it will be appreciated that the utility of the disclosure is not thus limited, but rather extends to and encompasses numerous other variations, modifications and alternative embodiments, as will suggest themselves to those of ordinary skill in the field of the present disclosure, based on the description herein. Correspondingly, the disclosure as hereinafter claimed is intended to be broadly construed and interpreted, as including all such variations, modifications and alternative embodiments, within its spirit and scope.

What is claimed is:

1. A gas supply assembly for delivery of gas to a plasma flood gun, comprising:
a fluid supply package configured to deliver inert gas to a plasma flood gun for generating inert gas plasma including electrons for modulating surface charge of a substrate in ion implantation operation; and
cleaning gas in the inert gas fluid supply package in mixture with the inert gas, or in a separate cleaning gas supply package configured to deliver cleaning gas to the plasma flood gun concurrently or sequentially with respect to delivery of inert gas to the plasma flood gun.

2. The gas supply assembly of claim 1, wherein the cleaning gas is in the inert gas fluid supply package in mixture with the inert gas.

3. The gas supply assembly of claim 1, wherein the cleaning gas is in a separate cleaning gas supply package, and the assembly further comprises flow circuitry configured to receive cleaning gas from the cleaning gas supply package and inert gas from the inert gas fluid supply package, for mixing thereof to form a mixture of cleaning gas and inert gas for dispensing to the plasma flood gun.

4. The gas supply assembly of claim 3, wherein the flow circuitry comprises a mixing chamber arranged to receive the cleaning gas and the inert gas from their respective fluid supply packages, for mixing thereof to form the mixture of cleaning gas and inert gas for dispensing to the plasma flood gun.

5. The gas supply assembly of claim 3, wherein the flow circuitry comprises valving configured to selectively enable mixing of the cleaning gas and the inert gas in the mixing chamber, and alternatively to selectively enable the cleaning gas and the inert gas to be flowed separately to the plasma flood gun.

6. The gas supply assembly of claim 3, further comprising a processor configured to control dispensing of cleaning gas from the cleaning gas supply package and dispensing of inert gas from the inert gas supply package.

7-8. (canceled)

9. The gas supply assembly of claim 1, wherein the cleaning gas comprises at least one gas selected from the group consisting of F₂, O₂, H₂, HF, SiF₄, GeF₄, NF₃, N₂F₄, COF₂, C₂F₄H₂, and CₓO_{z}H_{y}F_{w}, wherein w, x, y, and z are each independently of zero or non-zero stoichiometrically appropriate value.

10. The gas supply assembly of claim 1, wherein the inert gas comprises at least one of argon, helium, nitrogen, xenon, and krypton.

11. A plasma flood gun apparatus comprising the gas supply assembly of claim 1.

12. (canceled)

13. A method of operating a plasma flood gun configured to receive inert gas flowed to the plasma flood gun from an inert gas source, and to generate inert gas plasma therefrom including electrons energetically adapted to neutralize surface charge of a substrate being ion implanted, said method comprising introducing to the plasma flood gun, intermittently, continuously, or sequentially in relation to flow of inert gas to the plasma flood gun, a cleaning gas that is effective to generate volatile reaction product gases from material deposits in the plasma flood gun, and to effect re-metallization of a plasma generation filament in the plasma flood gun.

14. The method of claim 13, wherein the cleaning gas is introduced to the plasma flood gun intermittently in relation to flow of inert gas to the plasma flood gun.

15. The method of claim 13, wherein the cleaning gas is introduced to the plasma flood gun continuously in relation to flow of inert gas to the plasma flood gun.

16. The method of claim 13, wherein the cleaning gas is introduced to the plasma flood gun sequentially in relation to flow of inert gas to the plasma flood gun.

17. The method of claim 13, wherein the cleaning gas is flowed to the plasma flood gun in mixture with the inert gas.

18. The method of claim 13, wherein the cleaning gas and inert gas are provided to the plasma flood gun from separate gas supply packages.

19. The method of claim 18, wherein the cleaning gas and inert gas are mixed with one another and exteriorly of the plasma flood gun.

20. The method of claim 13, wherein the cleaning gas comprises at least one gas selected from the group consisting of F₂, O₂, H₂, HF, SiF₄, GeF₄, NF₃, N₂F₄, COF₂, C₂F₄H₂, and CₓO_{z}H_{y}F_{w}, wherein w, x, y, and z are each independently of zero or non-zero stoichiometrically appropriate value.

21. The method of claim 13, wherein the inert gas comprises at least one of argon, helium, nitrogen, xenon, and krypton.

22. (canceled)
